(19) United States
(12) Patent Application Publication
(10) Pub. No.: US 2023/0317634 A1
(43) Pub. Date: Oct. 5, 2023

(54) COATINGS WITH DIFFUSION BARRIERS FOR CORROSION AND CONTAMINATION PROTECTION

(71) Applicant: Applied Materials, Inc., Santa Clara, CA (US)

(72) Inventors: Jordi Perez Mariano, Redwood City, CA (US); Tony S. Kaushal, Campbell, CA (US)

(73) Assignee: Applied Materials, Inc., Santa Clara, CA (US)

(21) Appl. No.: 17/713,350

(22) Filed: Apr. 5, 2022

(51) Int. Cl. H01L 23/00; H01L 23/29; H01L 23/31; H01L 21/56

(52) U.S. Cl. CPC H01L 23/564; H01L 23/291; H01L 23/3192; H01L 21/56

(57) ABSTRACT

Exemplary methods of semiconductor processing are described. The methods are developed to increase corrosion resistance to a substrate, such as a metal substrate. The methods include forming a first oxygen-containing material on a substrate. The first oxygen-containing material may be or include silicon oxide, yttrium oxide, or aluminum oxide. The methods may include forming a barrier layer on the first oxygen-containing material. The methods may include forming a second oxygen-containing material on the barrier layer. The second oxygen-containing material may be or include silicon oxide, yttrium oxide, or aluminum oxide.

### TECHNICAL FIELD

The present technology relates to processes and systems for coating components. More specifically, the present technology relates to systems and methods for coating a substrate with a multilayer corrosion and contamination resistant coating.

### BACKGROUND

Semiconductor processing systems may include a number of components used to support substrates, deliver formation materials and removal materials, and define processing regions and flow paths. These components may be exposed to high and low temperatures, high and low pressures, and a variety of corrosive and erosive materials. Accordingly, many processing chambers include treated or coated materials. However, as processing systems and chambers become more complex, the components incorporated within the system may become multi-piece apparatuses that may include complex geometries and features across the components. These features may similarly be exposed to environmental conditions and materials that can cause damage to the components.

Thus, there is a need for improved systems and components that can be used to produce high quality devices and structures. These and other needs are addressed by the present technology.

### SUMMARY

Embodiments of the present technology include semiconductor processing methods that include forming a first oxygen-containing material on a substrate. The first oxygen-containing material may be or include silicon oxide, yttrium oxide, or aluminum oxide. The methods include forming a barrier layer on the first oxygen-containing material. The methods include forming a second oxygen-containing material on the barrier layer. The second oxygen-containing material may be or include silicon oxide, yttrium oxide, or aluminum oxide.

In some embodiments, the first oxygen-containing material and the second oxygen-containing material may be or include the same material. The substrate may include a metal component of a semiconductor processing chamber. The barrier layer may be characterized by a thickness of less than or about 25 nm. A thickness of the barrier layer may be less than or about 20% of a combined thickness of the first oxygen-containing material, the barrier layer, and the second oxygen-containing material. The barrier layer may be or include hafnium oxide, lanthanum oxide, aluminum oxide, tungsten, tungsten nitride, or titanium nitride. The barrier layer may be deposited by atomic layer deposition. The methods may include, subsequent to forming the second oxygen-containing material, exposing the substrate to a halogen-containing species. The barrier layer may reduce an amount of corrosion constituents interacting with the substrate.

Some embodiments of the present technology may encompass semiconductor processing methods. The methods may include i) forming an oxygen-containing material on a metal substrate. The oxygen-containing material may be or include silicon oxide, yttrium oxide, or aluminum oxide. The methods may include ii) forming a barrier material. The barrier material may overly the oxygen-containing material. The methods may include iii) repeating operations i and ii to form an alternating stack of oxygen-containing materials and barrier materials on the metal substrate.

In some embodiments, a temperature is maintained at less than or about 450° C. while forming the oxygen-containing materials and the barrier materials. The metal substrate may include a stainless steel or aluminum semiconductor processing chamber component. The alternating stack may include greater than three layers of barrier material. Each barrier material may be characterized by a thickness of less than or about 10% of a total thickness of the alternating stack of oxygen-containing materials and barrier materials. The methods may include iv) exposing the substrate to a halogen-containing species. The halogen-containing may include fluorine. The oxygen-containing material may be or include yttrium oxide and the barrier material may be or include lanthanum oxide.

Some embodiments of the present technology encompass semiconductor structures. The structures may include a substrate. The structures may include an oxygen-containing material on the substrate. The oxygen-containing material may be or include silicon oxide, yttrium oxide, or aluminum oxide. The structures may include one or more barrier layers interlaid within the oxygen-containing material. Each of the one or more barrier layers may be characterized by a thickness of less than or about 25 nm. A total thickness of the one or more barrier layers may be less than or about 50% of a combined thickness of the oxygen-containing material and the one or more barrier layers.

In some embodiments, the combined thickness of the oxygen-containing material and the one or more barrier layers may be between about 100 nm and about 500 nm. The substrate may include a metal substrate. Each of the one or more barrier layers may be conformally formed on the oxygen-containing material. The one or more barrier layers may be or include hafnium oxide, lanthanum oxide, aluminum oxide, tungsten, tungsten nitride, or titanium nitride.

The present technology provides numerous benefits over conventional corrosion resistant coatings for metal parts exposed to highly corrosive environments. Embodiments of the present technology form anticorrosive coatings that can withstand a highly corrosive halogen-containing atmosphere. In embodiments, the multilayer anticorrosive coatings includes one or more barrier layers interlaid within a main layer. Corrosion-resistant main layers such a silicon dioxide or a yttrium oxide can resist corrosion from aggressive halogen-containing species in, for example, a semiconductor fabrication apparatus. Additional barrier layers, such as metal oxides, metals, or metal nitrides, further increase the corrosion-resistivity of the corrosion-resistant main layers, thereby forming a highly corrosion-resistant multilayer coating. Barrier layers may also reduce outward movement of contaminating species from substrates that the multilayer coatings are formed on. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows selected operations in a method of forming a component according to some embodiments of the present technology.

FIG. 2 shows a schematic cross-sectional view of a portion of a component coated with a multilayer corrosion resistant coating according to embodiments of the invention.

FIG. 3 shows a schematic cross-sectional view of a portion of a component coated with a multilayer corrosion resistant coating according to additional embodiments of the invention.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Semiconductor processing includes operations that produce intricately patterned material on a substrate. The operations include remote and in-situ formation and removal processes that utilize corrosive materials, including hot gases and ionized plasmas of halogen-containing compounds, radicals, and ions. For example, etching operations often involve contacting a substrate with a halogen-containing liquid, gas, or plasma etchant that flows into a processing region of a processing apparatus. While the halogen-containing etchants are intended to etch wafers and other device substrates, they also react with the walls of a processing chamber and other equipment components to produce equipment corrosion. When the equipment components are made of metal such as stainless steel or aluminum, the halogen-containing materials can react rapidly to cause equipment wear and become a source of contaminants. Such contaminants may travel from the component to the substrate, contaminating the substrate and thereby affecting final device performance. Furthermore, over time, the corrosion increases equipment repair and replacement costs as well as increases down time for the processing apparatus.

Deposition processes similarly may use plasma enhanced processes or rapid thermal processing to form or deposit materials on substrates, which may also be deposited on chamber components. This may require cleaning operations once a substrate has been removed from the chamber. Cleaning processes may include utilizing one or more halogen-containing precursors or plasma effluents of these precursors to remove material deposited on surfaces in the processing chamber. While the cleaning may target deposited material, many exposed chamber component surfaces may be similarly attacked. For example, once the substrate has been removed from the processing chamber, a central region of the substrate support will be exposed with no residual deposition material. The cleaning process may begin to form pitting or other removal of the substrate support, which may reduce planarity, as well as integrity for a chuck.

Many of these chamber components include multiple pieces bonded together to produce channels, flow paths, or sealed regions within the component. Individual pieces or a combination apparatus component within the chamber may be characterized by any number of internal features, including channels, apertures, and a variety of other topographies.

Conventional technologies have struggled to limit both corrosion and erosion to chamber components and tend to replace components regularly due to the damage caused by one or both of these mechanisms. Although some processes may include a seasoning process prior to the semiconductor substrate processing, this may cause additional challenges. For example, seasoning processes may cover portions of the substrate support, but may not fully cover a backside or stem, and thus components of a substrate support, such as a baseplate or stem, may still be exposed to process and cleaning materials. Additionally, seasoning processes typically deposit a hundred nanometers of coating or less. This may require the seasoning to be replaced for each substrate being processed, which may increase queue times, and may also reduce the likelihood of a uniform or complete coverage. Conventional technologies have attempted to protect many of these components with coatings that may be less reactive to corrosive materials, and/or may be more capable of withstanding plasma bombardment.

Embodiments of the present technology addresses these and other issues by coating chamber components with a multilayer corrosion-resistant coating that also prevents the chamber components from contaminating structures being processed within the chamber. In embodiments, the multilayer coating includes a barrier layer formed between the main layer. In further embodiments, the multilayer coating may include a plurality of barrier layers interlaid within the main layer. When the component coated with the present multilayer coating undergoes processing, such as in an environment using a halogen-containing species, the main layer may reduce corrosion of the substrate. However, in the event any corrosion of the substrate does occur, the barrier layer(s) may prevent contaminants from escaping the multilayer coating. If contaminants were permitted to escape the multilayer coating, the contaminants may interact with structures or devices being processed. The multilayer coating of the present disclosure reduces corrosive species, such as halogen-containing species, from reaching the component while simultaneously reducing any contaminants from the component from reaching the chamber interior.

The remaining disclosure identifies specific materials, components, and semiconductor processing methods according to embodiments of the present technology. It is readily understood that the described methods, materials, components, and systems can apply to a variety of other methods, materials, components, and systems used for semiconductor device fabrication, and the fabrication of other kinds of devices where corrosion-resistant coatings protect components in the fabrication system or apparatus. Accordingly, the present technology is not limited to the described coating methods, materials, components, and systems. The disclosure will discuss non-limiting operations of exemplary coating methods as well as general components that may be coated according to embodiments of the present technology.

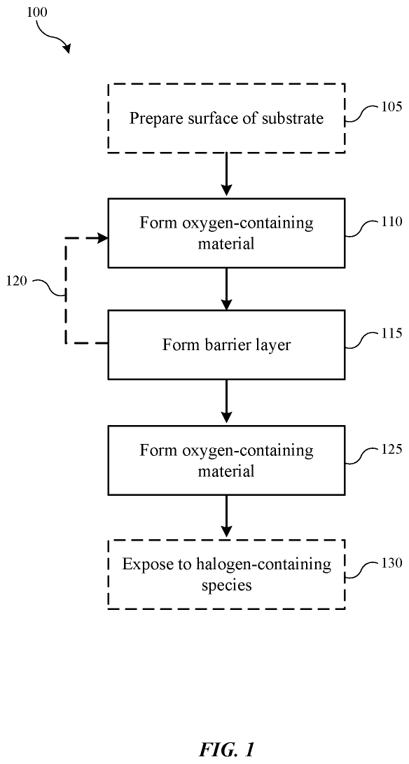

FIG. 1 shows selected operations in a method 100 of coating a semiconductor component substrate according to embodiments of the present technology. Many operations of method 100 may be performed, for example, in any number of chambers or systems, including oxidation chambers and atomic-layer deposition chambers, as well as any combination of systems discussed, or which may be configured to perform operations as discussed for method 100. Method 100 may include one or more operations prior to the first described operation, including processing to produce or prepare one or more parts or pieces which may be bonded, as well as components that have been bonded already. For example, upstream processing may include casting or treating metal components, as well as preparing one or more surfaces for coating operations. The method 100 may further include optional operations that may or may not be specifically associated with embodiments of the present method. For example, some embodiments of the present coating methods that provide a broader or alternative scope of the methods may include one or more operations that do not occur, or occur at a different time, in other embodiments of the methods.

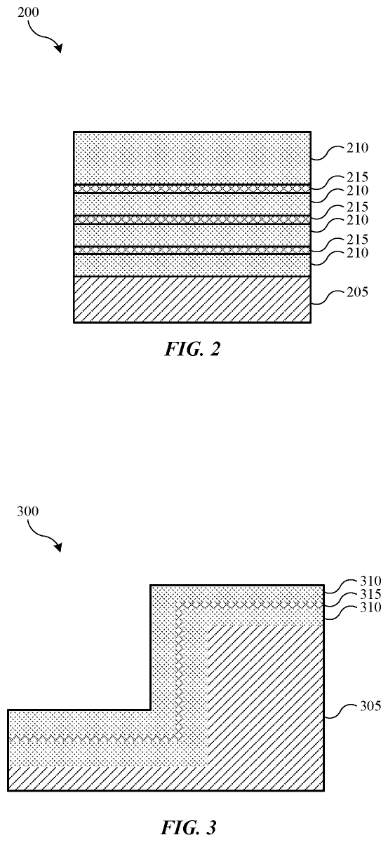

Method 100 will also be described in conjunction with the cross-sectional view of a portion of a component 200 shown in FIG. 2. Component 200 includes an embodiment of the present multilayer corrosion resistant coatings positioned on the surface of a substrate 205 that forms at least part of the component. In the embodiments shown in FIG. 2, the multilayer coating is a multilayer coating that include a main layer 210 and a barrier layer 215. It should be appreciated that the additional layers may be formed below the substrate 205 and above the main layer 210. It should also be appreciated that the interface between layers may or may not have a sharp boundary. For example, a portion of the interface may include a combination of materials from two adjacent layers, such as the main layer 210 and the barrier layer 215. In embodiments of the present technology, a coated component includes one or more substrate surfaces upon which the multilayer coating is formed. The substrate surfaces include exposed surfaces of the substrate that form a bonding layer of the multilayer coating. The substrate may include one or more metals that are incorporated into the at least a portion of the component, such as the walls of the component. In embodiments, the metal substrate may be or include any number of components or component sections. In additional embodiments, the metal substrate may be incorporated into a component of a semiconductor processing system that is used to conduct semiconductor fabrication operations that use corrosive liquids, gases, and plasmas. In still additional embodiments, the metal substrate may be incorporated into semiconductor fabrication equipment components such as baseplates or edge rings, fluid delivery components such as showerheads or lid plates, structural components such as spacers or liners, as well as other single or multi-piece components of semiconductor fabrication equipment that may be coated according to the present methods. The components may be substantially planar, or may include complex geometries, which may include channels, apertures, or other features across one or more surfaces of the components. The components may be made of any number of materials, which may be or include aluminum, carbon, chromium, copper, iron, magnesium, manganese, nickel, silicon, titanium, or zinc. The components may be or include alloys, such as iron alloys, which may include any number of materials. In many embodiments, the metal substrate in the component includes stainless steel, such as 316 stainless steel. Although the discussion below may reference stainless steel, from which components according to embodiments of the present technology may be made, it is to be understood that the present technology may be employed with any iron alloy, as well as alloys of any number of other metals that may be used in semiconductor processing chambers or systems.

In embodiments, method 100 may include preparing a surface of a substrate 205 at optional operation 105. In further embodiments, the preparations may include one or more of removing an existing coating from the substrate surface, roughening the substrate surface, smoothing the substrate surface, exposing the substrate surface to an oxidizing environment, exposing the substrate surface to a passivating environment, and exposing the substrate surface to an etching environment, among other preparations. In some embodiments, substrate surface preparation at optional operation 105 may be bypassed because the substrate surface is already primed to form the multilayer coating.

In additional embodiments, substrate surface preparation at optional operation 105 may include the removal of oxides, organics, oil, soil, particulate, debris, and/or other contaminants, from the surface of the substrate 205. In further embodiments, the preparations may include blasting or texturing the surface, exposing the surface to a vacuum, solvent cleaning the surface, acid cleaning the surface, wet cleaning the surface, plasma cleaning the surface, and sonication of the surface, among other preparations. The prepared surface of the substrate 205 may be characterized by faster formation and stronger bonding of a multilayer coating on the surface compared to an unprepared substrate surface.

In further embodiments, the preparation of the substrate surface may include blasting or otherwise exposing the surface to one or more kinds of abrasive particulates such as beads, sand, and carbonates, solid carbon dioxide (CO₂), among other kinds of particulates. In embodiments, the particulate exposure removes oxides and other contaminates from the substrate surface and may also provide texturing to the surface of the substrate 205. In more embodiments, the preparation of the substrate surface may include placing the component 200 into a chamber within a pulsed push-pull gas cycling system and exposing the substrate surface of the component to at least one cycle of a purge gas such as nitrogen, argon, helium, and mixtures thereof. In further embodiments, the component 200 may be exposed to at least one vacuum purge to remove particulates and other debris from the substrate surface. In still more embodiments, the component 200 may be placed into a plasma chamber and the substrate surface may be exposed to one or more kinds of plasma, such as a hydrogen-containing plasma, an oxygen- or ozone-containing plasma, and a nitrogen-containing plasma, among other kinds of plasma. In yet more embodiments, the plasma may be generated in situ, or may be remotely generated outside the chamber holding the component 200 and delivered to the chamber.

In more embodiments, the preparation of the substrate surface may include removal of one or more organic compounds and oxide compounds from the surface of the substrate 205. In additional embodiments, organic and oxide compounds may be removed from the surface by a reducing plasma, such as a hydrogen plasma. In more embodiments, the reduced organic and oxide compounds may be degassed from the surface and exposed to ozone. In still more embodiments, the preparation of the substrate surface may include a wet clean to remove organic compounds from the surface. In embodiments the wet clean may include soaking the substrate surface in an alkaline degreasing solution, rinsing, exposing the surface to an acid clean (e.g., sulfuric acid, phosphoric acid, or hydrochloric acid), rinsing again, and exposing the surfaces deionized water sonication bath. In yet additional embodiments, the preparation of the substrate surface may include a wet clean to remove oxide compounds from the surface. In embodiments the wet clean may include exposing the substrate surface to a dilute acid solution (e.g., acetic acid or hydrochloric acid), rinsing, and exposing the surface to deionized water in a sonication bath. In further embodiments, the preparation of the substrate surface may include a preparation operation to remove particles from the substrate surface. In embodiments, these particle removal preparations may include exposing the substrate surface to sonication (e.g., megasonication) and/or a supercritical carbon dioxide wash, followed by exposing to cycles of purge gas (e.g., N₂, Ar, He, or any combination thereof) and vacuum purges to remove particles from and dry the surfaces. In yet further embodiments, the preparation of the substrate surface may include exposing the surface to heating and drying operations. In embodiments, the heating operation may include exposing the substrate surface to a temperature above room temperature. In additional embodiments the elevated temperature may be characterized as a temperature greater than or about 50° C., greater than or about 75° C., greater than or about 100° C., greater than or about 125° C., greater than or about 150° C., greater than or about 175° C., greater than or about 200° C., or more. In more embodiments, the heating operation may include exposing the substrate surface to a heat lamp or placing the component in an oven.

Method 100 may further include forming main layer 210, such as a first portion of the main layer 210 or a first oxygen-containing material on the substrate 205 at operation 110. In embodiments, the oxygen-containing material of the main layer 210 may include a silicon oxide such as silicon dioxide. In further embodiments, the silicon oxide (e.g., SiO₂) in the main layer may be greater than or about 50 wt. %, greater than or about 60 wt. %, greater than or about 70 wt. %, greater than or about 80 wt. %, greater than or about 90 wt. %, greater than or about 95 wt. % or more of the total weight of the main layer 210. In yet further embodiments, the main layer 210 may be deposited by a vapor deposition process such as atomic layer deposition (ALD), plasma-enhanced atomic layer deposition (PE-ALD), thermal chemical vapor deposition (CVD), and plasma-enhanced chemical vapor deposition (PE-CVD), among other vapor deposition processes. In further embodiments, the deposition process may include an ALD process that provides a semiconductor- or metal-containing reactant and an oxidizing reactant to a deposition processing region where they form a silicon oxide containing layer on at least a portion of the substrate 205. The semiconductor- or metal-containing reactant and the oxidizing reactant deposit main layer 210 on the substrate 205. In additional embodiments, the semiconductor- or metal-containing reactant may include a silicon-containing reactant such as silane, a silicon chloride, a silicon cyanate, an oxysilane, or an aminosilane, among other silicon-containing reactants. In still additional embodiments, the silane may include one or more of silane, disilane, trisilane, tetrasilane, pentasilane, and hexasilane, among other silanes. In yet further embodiments, the silicon chlorides may include one or more of monochlorosilane, dichlorosilane, trichlorosilane, tetrachlorosilane, and hexachlorosilane, among other silicon chlorides. In more embodiments, the silicon cyanates may include tetraisocyanatosilane, among other silicon cyanates. In yet more embodiments, the oxysilanes may include tetraethoxysilane, among other oxysilanes. In additional embodiments, the aminosilanes may include tris(dimethyloamino)silane, bis(ethyl-methylamino)silane, among other aminosilanes. In additional embodiments, the oxidizing reactant can include one or more of water (e.g., steam), oxygen (O₂), atomic oxygen (O), ozone (O₃), nitrous oxide, one or more peroxides, one or more alcohols, plasmas thereof, or any combination thereof. In further embodiments, one or both of the silicon-containing reactant and the oxidizing reactant may include one or more carrier gases such as nitrogen (N₂), argon, helium, neon, and hydrogen (H₂), among other carrier gases.

In more embodiments, the atomic layer deposition of the main layer 210 may include one or more cycles of exposing the substrate 205 to the semiconductor- or metal-containing reactant, conducting a purge-pump operation of the deposition processing region to remove residual metal-containing reactant, exposing the component to the oxidizing reactant, and conducting another purge-pump operation to remove residual oxidizing reactant from the deposition processing region. In still more embodiments, the ALD operation may include greater than or about 1 cycle, greater than or about 2 cycles, greater than or about 3 cycles, greater than or about 4 cycles, greater than or about 5 cycles, greater than or about 8 cycles, greater than or about 10 cycles, greater than or about 15 cycles, greater than or about 20 cycles, greater than or about 30 cycles, greater than or about 50 cycles, greater than or about 80 cycles, greater than or about 100 cycles, greater than or about 150 cycles, greater than or about 200 cycles, greater than or about 250 cycles, greater than or about 300 cycles, greater than or about 350 cycles, greater than or about 400 cycles, greater than or about 450 cycles, greater than or about 500 cycles, or more. In still more embodiments, each cycle may deposit a portion of the main layer 210 characterized by a thickness of less than or about 25 nm, less than or about 20 nm, less than or about 17.5 nm, less than or about 15 nm, less than or about 12.5 nm, less than or about 10 nm, less than or about 7.5 nm, less than or about 5 nm, or less.

In additional embodiments, the oxygen-containing material of the main layer 210 may include a yttrium oxide such as diyttrium trioxide. In further embodiments, the yttrium oxide (e.g., Y₂O₃) in the main layer 210 may be greater than or about 50 wt. %, greater than or about 60 wt. %, greater than or about 70 wt. %, greater than or about 80 wt. %, greater than or about 90 wt. %, greater than or about 95 wt. % or more of the total weight of the main layer 210. Similar to the silicon oxide material previously discussed, the yttrium oxide may be deposited by a vapor deposition process such as ALD, PE-ALD, CVD, and PE-CVD, among other vapor deposition processes. In further embodiments, the deposition process may include an ALD process that provides a semiconductor- or metal-containing reactant and an oxidizing reactant to a deposition processing region where they form a yttrium oxide containing layer on at least a portion of the substrate 205. The semiconductor- or metal-containing reactant and the oxidizing reactant deposit main layer 210 on the substrate 205. In additional embodiments, the semiconductor- or metal-containing reactant may include a yttrium-containing reactant such as tris(N,N-bis(trimethylsilyl)amide)yttrium (III), yttrium (III)butoxide, yttrium(III) chloride, tris(methylcyclopentadienyl)yttrium, tris(butylcyclopentadienyl)yttrium, tris(cyclopentadienyl)yttrium, among other yttrium-containing reactants.

In still more embodiments, the oxygen-containing material of the main layer 210 may include an aluminum oxide. In further embodiments, the aluminum oxide (e.g., Al₂O₃) in the main layer 210 may be greater than or about 50 wt. %, greater than or about 60 wt. %, greater than or about 70 wt. %, greater than or about 80 wt. %, greater than or about 90 wt. %, greater than or about 95 wt. % or more of the total weight of the barrier layer 215. In yet further embodiments, the aluminum oxide-containing main layer 210 may be deposited by a vapor deposition process such as ALD, PE-ALD, CVD, and PE-CVD, among other vapor deposition processes. In further embodiments, the deposition process may include an ALD process that provides a semiconductor- or metal-containing reactant and an oxidizing reactant to a deposition processing region where they form an aluminum oxide containing layer on at least a portion of the substrate 205. The semiconductor- or metal-containing reactant and the oxidizing reactant deposit main layer 210 on the substrate 205. In additional embodiments, the semiconductor- or metal-containing reactant may include an aluminum-containing reactant such as one or more of aluminum alkyl compounds, one or more of aluminum alkoxy compounds, and one or more of aluminum acetylacetonate compounds, among other aluminum-containing reactants. In still more embodiments, the aluminum-containing reactant can include trimethylaluminum, triethylaluminum, tripropylaluminum, tributylaluminum, trimethoxyaluminum, triethoxyaluminum, tripropoxyaluminum, tributoxyaluminum, aluminum acetylacetonate (Al(acac)₃, also known as, tris(2,4-pentanediono) aluminum), aluminum hexafluoroacetylacetonate (Al(hfac)₃), and trisdipivaloylmethanatoaluminum (DPM₃Al; (C₁₁H₁₉O₂)₃Al), among other aluminum-containing reactants.

Method 100 may further include forming the barrier layer 215 at operation 115. The barrier layer 215 may be conformally formed on the main layer 210. In embodiments, the barrier layer 215 may include a hafnium oxide. In further embodiments, the hafnium oxide (e.g., HfO₂) in the barrier layer 215 may be greater than or about 50 wt. %, greater than or about 60 wt. %, greater than or about 70 wt. %, greater than or about 80 wt. %, greater than or about 90 wt. %, greater than or about 95 wt. % or more of the total weight of the barrier layer 215. In yet further embodiments, the hafnium oxide-containing barrier layer 215 may be deposited by a vapor deposition process such as ALD, PE-ALD, CVD, and PE-CVD, among other vapor deposition processes. In further embodiments, the deposition process may include an ALD process that provides a hafnium-containing reactant and an oxidizing reactant to a deposition processing region that has exposure to at least a portion of the main layer 210 formed on the component 200. In additional embodiments, the hafnium-containing reactant may include hafnium cyclopentadiene compounds, hafnium amino compounds, hafnium alkyl compounds, and hafnium alkoxy compounds, among other hafnium-containing reactants. In more embodiments, the hafnium-containing reactants may include bis(methylcyclopentadiene) dimethylhafnium ((MeCp)₂HfMe₂), bis(methylcyclopentadiene) methylmethoxyhafnium ((MeCp)₂Hf(OMe)(Me)), bis(cyclopentadiene) dimethylhafnium ((Cp)₂HfMe₂), tetra(tert-butoxy) hafnium, hafniumum isopropoxide ((iPrO)₄Hf), tetrakis(dimethylamino) hafnium (TDMAH), tetrakis(diethylamino) hafnium (TDEAH), and tetrakis(ethylmethylamino) hafnium (TEMAH), among other hafnium-containing reactants.

In further embodiments, the barrier layer 215 may include a lanthanum oxide. In further embodiments, the lanthanum oxide (e.g., HfO₂) in the barrier layer 215 may be greater than or about 50 wt. %, greater than or about 60 wt. %, greater than or about 70 wt. %, greater than or about 80 wt. %, greater than or about 90 wt. %, greater than or about 95 wt. % or more of the total weight of the barrier layer 215. In yet further embodiments, the lanthanum oxide-containing barrier layer 215 may be deposited by a vapor deposition process such as ALD, PE-ALD, C VD, and PE-CVD, among other vapor deposition processes. In further embodiments, the deposition process may include an ALD process that provides a lanthanum-containing reactant and an oxidizing reactant to a deposition processing region that has exposure to at least a portion of the main layer 210 formed on the component 200. In additional embodiments, the lanthanum-containing reactant may include lanthanum cyclopentadiene compounds, lanthanum amino compounds, lanthanum alkyl compounds, and lanthanum alkoxy compounds, among other lanthanum-containing reactants. In more embodiments, the lanthanum-containing reactants may include lanthanum(III) chloride, tris(i-propylcyclopentadienyl)lanthanum, tris(cyclopentadienyl)lanthanum,lanthanum(III) i-propoxide, lanthanum(III) acetylacetonate hydrate, tris(N,N-di-i-propylpentylamidinato)lanthanum(III), tris(N,N-bis(trimethylsilyl)amide)lanthanum(III), tris(N,N′-di-i-propylformamidinato)lanthanum(III), tris(6,6,7,7,8,8,8-heptafluoro-2,2-dimethyl-3,5-octanedionate)lanthanum(III), tris(2,2,6,6-tetramethyl-3,5-heptanedionato)lanthanum(III), among other lanthanum-containing reactants.

In yet additional embodiments, the barrier layer 215 may include oxides of one or more additional metals such as aluminum, chromium, magnesium, nickel, titanium, and zirconium, among other metals.

In more embodiments, the barrier layer 215 may include tungsten. The tungsten in the barrier layer 215 may be greater than or about 50 wt. %, greater than or about 60 wt. %, greater than or about 70 wt. %, greater than or about 80 wt. %, greater than or about 90 wt. %, greater than or about 95 wt. % or more of the total weight of the barrier layer 215. In yet further embodiments, the tungsten-containing barrier layer 215 may be deposited by a vapor deposition process such as ALD, PE-ALD, CVD, and PE-CVD, among other vapor deposition processes. In further embodiments, the deposition process may include an ALD process that provides a tungsten-containing reactant and a hydrogen-containing coreactant to a deposition processing region that has exposure to at least a portion of the main layer 210 formed on the component 200. The hydrogen-containing coreactant may serve only a sacrificial role to strip material from tungsten without incorporating into the film. In additional embodiments, the tungsten-containing reactant can include one or more of tungsten disulfide, tungsten hexafluoride, tungsten pentafluoride, among other tungsten-containing reactants. In additional embodiments, the hydrogen-containing coreactant can include one or more of silane, disilane, trisilane, or any other hydrogen-containing reactant.

In yet additional embodiments, the barrier layer 215 may include one or more additional metals such as aluminum, chromium, magnesium, nickel, titanium, and zirconium, among other metals.

In still more embodiments, the barrier layer 215 may include tungsten nitride. The tungsten nitride (e.g., W₂N, WN, WN₂) in the barrier layer 215 may be greater than or about 50 wt. %, greater than or about 60 wt. %, greater than or about 70 wt. %, greater than or about 80 wt. %, greater than or about 90 wt. %, greater than or about 95 wt. % or more of the total weight of the barrier layer 215. In yet further embodiments, the tungsten nitride-containing barrier layer 215 may be deposited by a vapor deposition process such as ALD, PE-ALD, CVD, and PE-CVD, among other vapor deposition processes. In further embodiments, the deposition process may include an ALD process that provides a tungsten-containing reactant and a nitrogen-containing reactant to a deposition processing region that has exposure to at least a portion of the main layer 210 formed on the component 200. In additional embodiments, the tungsten-containing reactant can include one or more of tungsten disulfide, tungsten hexafluoride, tungsten pentafluoride, among other tungsten-containing reactants. In additional embodiments, the nitrogen-containing reactant can include one or more of diatomic nitrogen, a combination of diatomic nitrogen and diatomic hydrogen, ammonia, plasmas thereof, or any other nitrogen-containing reactant.

In still more embodiments, the barrier layer 215 may include titanium nitride. The titanium nitride (e.g., TiN) in the barrier layer 215 may be greater than or about 50 wt. %, greater than or about 60 wt.%, greater than or about 70 wt. %, greater than or about 80 wt. %, greater than or about 90 wt. %, greater than or about 95 wt. % or more of the total weight of the barrier layer 215. In yet further embodiments, the titanium nitride-containing barrier layer 215 may be deposited by a vapor deposition process such as ALD, PE-ALD, CVD, and PE-CVD, among other vapor deposition processes. In further embodiments, the deposition process may include an ALD process that provides a titanium-containing reactant and a nitrogen-containing reactant to a deposition processing region that has exposure to at least a portion of the main layer 210 formed on the component 200. In additional embodiments, the titanium-containing reactant can include one or more of titanium tetrachloride (TiCl₄), tetrakis(dimethylamino)titanium(IV), tetrakis(diethylamino)titanium(IV), tetrakis(ethylmethylamino)titanium(IV), titanium(IV) i-propoxid, bis(t-butylcyclopentadienyl)titanium dichloride, bis(cyclopentadienyl)titanium dichloride, among other titanium-containing reactants. In additional embodiments, the nitrogen-containing reactant can include one or more of diatomic nitrogen, a combination of diatomic nitrogen and diatomic hydrogen, ammonia, plasmas thereof, or any other nitrogen-containing reactant.

In yet additional embodiments, the barrier layer 215 may include nitrides of one or more additional metals such as aluminum, chromium, magnesium, nickel, and zirconium, among other metals.

A temperature while forming the main layer 210 and/or barrier layer 215 may be maintained at less than or about 450° C. As the layers may be deposited through ALD, higher temperatures may cause precursors used to form the layers to decompose prior to depositing on the surface of the substrate 205 and/or main layer 210, which may impact deposition. Accordingly, the temperature may be maintained at less than or about 400° C., less than or about 350° C., less than or about 300° C., less than or about 250° C., less than or about 200° C., less than or about 150° C., less than or about 100° C., or less.

Method 100 may further include repeatedly forming portions of the main layer 210 and the barrier layer 215 at optional operation 120. As illustrated in the embodiment of FIG. 2, the component 200 includes three barrier layers 215 disposed between four portions of the main layer 210. While illustrated with the main layer 210 being in contact with the substrate 205, it is contemplated that the barrier layer 215 may alternatively be in contact with the substrate 205. Similarly, while illustrated with the main layer 210 being the uppermost layer on the component 200, it is contemplated that the barrier layer 215 may alternatively be the uppermost layer. In embodiments, the component may include any number of alternating layers of the main layer 210 and the barrier layer 215. For example, the component 200 may include greater than three layers of barrier material, greater than four layers of barrier material, greater than five layers of barrier material, greater than ten layers of barrier material, greater than fifteen layers of barrier material, greater than twenty layers of barrier material, greater than twenty-five layers of barrier material, greater than thirty layers of barrier material, greater than thirty-five layers of barrier material, or more.

Method 100 may further include forming additional main layer 210, such as a second portion of the main layer 210 or a second oxygen-containing material, on the barrier layer 215 at operation 125. In embodiments, the second portion of the main layer 210 formed at operation 125 may be the same material formed at operation 110. For example, when silicon oxide is formed at operation 110, additional silicon oxide may be formed over the barrier layer 215 at operation 125. However, it is contemplated that the main layer 210 may include different materials on opposing sides of the barrier layer 215.

In embodiments, the corrosion resistance of the coated component 200 may be increased by increasing a thickness of the main layer 210 and/or the barrier layer 215. The more material a corrosive substance has to penetrate or remove to reach the surface of substrate 205, the longer the coated component can resist the corrosive effects of the corrosive substance. In further embodiments, the multilayer coating, including main layer(s) 210 and barrier layer(s) 215 may be characterized by a thickness of greater than or about 50 nm, greater than or about 75 nm, greater than or about 100 nm, greater than or about 125 nm, greater than or about 150 nm, greater than or about 175 nm, greater than or about 200 nm, greater than or about 225 nm, greater than or about 250 nm, greater than or about 275 nm, greater than or about 300 nm, greater than or about 350 nm, greater than or about 400 nm, greater than or about 450 nm, greater than or about 500 nm, or more. As many embodiments include ALD depositions which may require significant processing times, the multilayer coating may be characterized by a thickness of less than or about 750 nm, less than or about 700 nm, less than or about 650 nm, less than or about 600 nm, less than or about 550 nm, less than or about 500 nm, less than or about 450 nm, less than or about 400 nm, less than or about 350 nm, less than or about 300 nm, less than or about 250 nm, less than or about 200 nm, less than or about 150 nm, less than or about 100 nm, or less. In embodiments, the combined thickness of the main layer 210, such as the oxygen-containing material, and the one or more barrier layers 215 may be between about 100 nm and about 500 nm.

In additional embodiments, the barrier layer 215 may be characterized by a thickness of less than or about 25 nm, less than or about 20 nm, less than or about 17.5 nm, less than or about 15 nm, less than or about 12.5 nm, less than or about 10 nm, less than or about 7.5 nm, less than or about 5 nm, or less. In further embodiments, the thickness of the barrier layer 215 may be related to the thickness of the multilayer coating, which may include any portions of the main layer 210 (e.g., oxygen-containing material) and the barrier layer(s) 215. For example, the thickness of the barrier layer 215 may less than or about 20% of a combined thickness of the multilayer coating, such as less than or about 17.5%, less than or about 15%, less than or about 12.5%, less than or about 10%, less than or about 7.5%, less than or about 5%, or less. In embodiments having multiple barrier layers 215, a total thickness of the one or more barrier layers 215 may be less than or about 50% of a combined thickness of the multilayer coating, such as less than or about 45%, less than or about 40%, less than or about 35%, less than or about 30%, less than or about 25%, less than or about 20%, less than or about 15%, less than or about 10%, less than or about 5%, or less.

Method 100 may include exposing the component 200 with the multilayer coating to a one or more corrosive substances at optional operation 130. The one or more corrosive substances may include halogen-containing species, such as fluorine, chlorine, and bromine. In embodiments, the halogen-containing species may be included in a halogen-containing compound, radical, or ion, incorporated into a halogen-containing liquid, solution, precursor, gas, or plasma, among other halogen-containing mediums. For example, chlorine-containing corrosive substances may include one or more of hydrogen chloride or hydrochloric acid (HCl), molecular chlorine (Cl₂), chlorine radicals (Cl), and oxygen-and-chlorine-containing compounds, nitrogen-and-chlorine-containing compounds, and carbon-and-chlorine-containing compounds, among other chlorine-containing substances. For example, fluorine-containing corrosive substances may include one or more of nitrogen fluoride (NF₃), sulfur hexafluoride (SF₆), carbon tetrafluoride (CF₄), hexafluoroethane, other carbon-and-fluorine-containing compounds, among other fluorine-containing substances.

The main layer 210 and/or the barrier layer 215 may be characterized by a higher corrosion resistance to one or more corrosive substances relative to the substrate 205 of the component 200. In embodiments, a halogen etch rate ratio of the substrate surface to the main layer 210 and/or the barrier layer 215 may be characterized as greater than or about 10:1, greater than or about 50:1, greater than or about 100:1, greater than or about 200:1, greater than or about 300:1, greater than or about 400:1, greater than or about 500:1, greater than or about 600:1, greater than or about 700:1, greater than or about 800:1, greater than or about 900:1, greater than or about 1000:1, or more. In additional embodiments, the main layer 210 and/or the barrier layer 215 may reduce the coated component's corrosion rate from chlorine-containing corrosive substances compared to the corrosion rate for the substrate 205 of an uncoated component. In still additional embodiments, the barrier layer 215 may reduce the coated component's corrosion rate to less than or about 90%, less than or about 80%, less than or about 70%, less than or about 60%, less than or about 50%, less than or about 40%, less than or about 30%, less than or about 20%, less than or about 10%, less than or about 5%, less than or about 1%, or less of the corrosion rate of the uncoated component.

In embodiments, the barrier layer 215 may reduce the ability of contaminants from the substrate 205 to pass through the multilayer coating of the component 200. If halogen-containing species do reach the substrate 205 and result in any corrosion, the barrier layer 215 may reduce or prevent any formed contaminants from passing through the multilayer coating. If contaminants were able to pass through the multilayer coating, these contaminants could interact with structures, such as wafers, being processed near the component 200. Such contamination of nearby structures may result in diminished performance of processed structures and/or final devices.

FIG. 3 show a cross-sectional view of a portion of a component 300 coated with a multilayer corrosion resistant coating according to additional embodiments of the invention. The substrate 305 of component 300 include a step to illustrate the conformality of the main layer 310 and the barrier layer 315 to steps, trenches, apertures, channels, fluid paths, tubes, and openings among other shapes of the substrate of the component. In embodiments, the present technology includes the formation of conformal coatings, which may extend across any variety of features and aspects of components. In embodiments, the conformality of the coating may be characterized by a low variation in the thickness of the multilayer coating on orthogonal surfaces of the step in the substrate 305. In embodiments, the variation in the thickness of the multilayer coating between orthogonal surfaces may be characterized as less than or about 10%, less than or about 7.5%, less than or about 5%, less than or about 2.5%, less than or about 1%, or less.

In additional embodiments, the component 300 may include one or more apertures (not shown) characterized by an aspect ratio (i.e., a height to width ratio) of greater than or about 1:1, greater than or about 2:1, greater than or about 3:1, greater than or about 4:1, greater than or about 5:1, greater than or about 6:1, greater than or about 7:1, greater than or about 8:1, greater than or about 10:1, or more. In still additional embodiments, the multilayer coating may be characterized by a high degree of uniformity on the interior walls of an aperture compared with other portions of the coating. In embodiments, the uniformity of the multilayer coating between the interior walls of the aperture and other portions of the coating may be characterized as having a thickness within 90% of each other and may be characterized by a thickness within 92% of each other, within 94% of each other, within 96% of each other, within 98% of each other, within 99% of each other, or essentially equivalent to each other within a margin of error for any measurement device or technology being used.

The present technology includes components, such as metal-containing chamber components, coated with a multilayer coating that provides the component with increased corrosion resistance. In embodiments, the multilayer coating includes one or more barrier layers that reduce the possibility of contamination of structures or devices being processed in the chamber. The main layer of the multilayer coating reduces corrosive effects of corrosive species, such as halogen-containing species, on the coated component. The barrier layer(s) reduce the possibility of contaminants from the component, in the event corrosion does occur, from reaching the chamber. If barrier layers are not present to block contaminants from travelling from the coated component out of the multilayer coating, these contaminants may negatively impact operations within the chamber by contaminating structures or devices being processed. In embodiments, components coated with the present multilayer coatings have extended operational lifetimes compared to uncoated components and also prevent contaminants from the component from passing through the multilayer coating.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where neither of the limits, either limit, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
forming a first oxygen-containing material on a substrate, wherein the first oxygen-containing material comprises silicon oxide, yttrium oxide, or aluminum oxide;
forming a barrier layer on the first oxygen-containing material; and
forming a second oxygen-containing material on the barrier layer, wherein the second oxygen-containing material comprises silicon oxide, yttrium oxide, or aluminum oxide.

2. The semiconductor processing method of claim 1, wherein the first oxygen-containing material and the second oxygen-containing material comprise the same material.

3. The semiconductor processing method of claim 1, wherein the substrate comprises a metal component of a semiconductor processing chamber.

4. The semiconductor processing method of claim 1, wherein the barrier layer is characterized by a thickness of less than or about 25 nm.

5. The semiconductor processing method of claim 1, wherein a thickness of the barrier layer is less than or about 20% of a combined thickness of the first oxygen-containing material, the barrier layer, and the second oxygen-containing material.

6. The semiconductor processing method of claim 1, wherein the barrier layer comprises hafnium oxide, lanthanum oxide, aluminum oxide, tungsten, tungsten nitride, or titanium nitride.

7. The semiconductor processing method of claim 1, wherein the barrier layer is deposited by atomic layer deposition.

8. The semiconductor processing method of claim 1, further comprising:
subsequent to forming the second oxygen-containing material, exposing the substrate to a halogen-containing species, wherein the barrier layer reduces an amount of corrosion constituents interacting with the substrate.

9. A semiconductor processing method comprising:
i) forming an oxygen-containing material on a metal substrate, wherein the oxygen-containing material comprises silicon oxide, yttrium oxide, or aluminum oxide;
ii) forming a barrier material, wherein the barrier material overlies the oxygen-containing material; and
iii) repeating operations i and ii to form an alternating stack of oxygen-containing materials and barrier materials on the metal substrate.

10. The semiconductor processing method of claim 9, wherein a temperature is maintained at less than or about 450° C. while forming the oxygen-containing materials and the barrier materials.

11. The semiconductor processing method of claim 9, wherein the metal substrate comprises a stainless steel or aluminum semiconductor processing chamber component.

12. The semiconductor processing method of claim 9, wherein the alternating stack comprises greater than three layers of barrier material.

13. The semiconductor processing method of claim 9, wherein each barrier material is characterized by a thickness of less than or about 10% of a total thickness of the alternating stack of oxygen-containing materials and barrier materials.

14. The semiconductor processing method of claim 9, further comprising:
iv) exposing the substrate to a halogen-containing species.

15. The semiconductor processing method of claim 14, wherein:
the halogen-containing species comprises fluorine;
the oxygen-containing material comprises yttrium oxide; and
the barrier material comprises lanthanum oxide.

16. A semiconductor structure comprising:
a substrate;
an oxygen-containing material on the substrate, wherein the oxygen-containing material comprises silicon oxide, yttrium oxide, or aluminum oxide; and
one or more barrier layers interlaid within the oxygen-containing material, wherein each of the one or more barrier layers is characterized by a thickness of less than or about 25 nm, and wherein a total thickness of the one or more barrier layers is less than or about 50% of a combined thickness of the oxygen-containing material and the one or more barrier layers.

17. The semiconductor structure of claim 16, wherein the combined thickness of the oxygen-containing material and the one or more barrier layers is between about 100 nm and about 500 nm.

18. The semiconductor structure of claim 16, wherein the substrate comprises a metal substrate.

19. The semiconductor structure of claim 16, wherein each of the one or more barrier layers are conformally formed on the oxygen-containing material.

20. The semiconductor structure of claim 16, wherein the one or more barrier layers comprise hafnium oxide, lanthanum oxide, aluminum oxide, tungsten, tungsten nitride, or titanium nitride.
